(19) United States
(12) Patent Application Publication
(10) Pub. No.: US 2009/0025785 A1
(43) Pub. Date: Jan. 29, 2009

(54) SOLAR CELL WITH FLEXIBLE SUBSTRATE

(75) Inventor: GA-LANE CHEN, Santa Clara, CA (US)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/967,008

(22) Filed: Dec. 29, 2007

(30) Foreign Application Priority Data
Jul. 27, 2007 (CN) 200710201194.1

(51) Int. Cl. H01L 31/028; H01L 31/0304

(52) U.S. Cl. 136/256; 136/252; 136/258; 136/262

(57) ABSTRACT

An exemplary solar cell includes a flexible substrate, a back metal contact layer, a P-type semiconductor layer, a P-N junction layer, an N-type semiconductor layer, and a front metal contact layer. The substrate is made of stainless steel. The back metal contact layer is formed on the substrate. The P-type semiconductor layer is formed on the back metal contact layer. The P-N junction layer is formed on the P-type semiconductor layer. The N-type semiconductor layer is formed on a P-N junction layer. The front metal contact layer is formed on the N-type semiconductor layer.

### BACKGROUND

1. Technical Field

The present invention relates to a solar cell with a flexible substrate.

2. Description of Related Art

A solar cell is a device that converts light energy into electrical energy. The solar cell is a clean energy power supply source. Nowadays, solar cells are widely used in buildings.

Generally, solar cells use glass substrates, monocrystalline silicon substrates, polycrystalline silicon substrates, and etc. However, these substrates are not very flexible, and the solar cells using these substrates are also not very flexible, which limits the usefulness of the solar cells. For example, when these solar cells are used on a surface of a building, it is difficult to arrange them to conform the shape of the building.

Therefore, a flexible solar cell is desired to overcome the above described shortcomings.

### SUMMARY

An exemplary solar cell includes a flexible substrate, a back metal contact layer, a P-type semiconductor layer, a P-N junction layer, an N-type semiconductor layer, and a front metal contact layer. The substrate is made of stainless steel. The back metal contact layer is formed on the substrate. The P-type semiconductor layer is formed on the back metal contact layer. The P-N junction layer is formed on the P-type semiconductor layer. The N-type semiconductor layer is formed on a P-N junction layer. The front metal contact layer is formed on the N-type semiconductor layer.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic, cross-sectional view of a solar cell according to a present embodiment.

FIG. 2 is a schematic, cross-sectional view of an apparatus for making the solar cell of FIG. 1.

### DETAILED DESCRIPTION OF THE EMBODIMENTS

Embodiments will now be described in detail below with reference to the drawings.

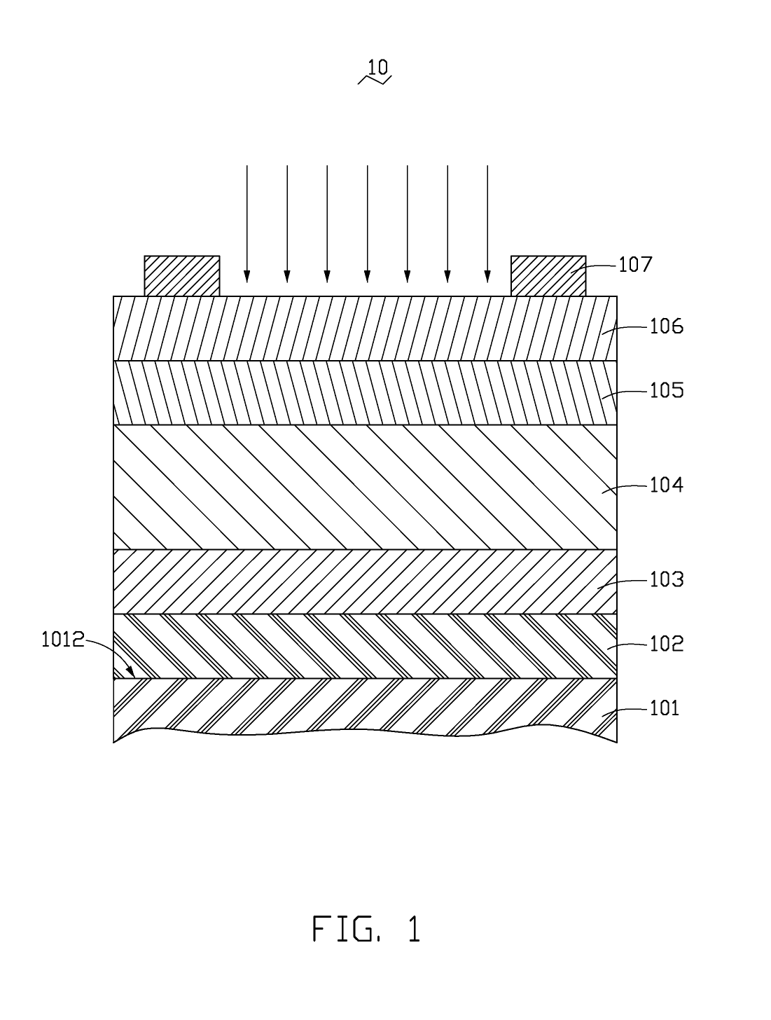

Referring to FIG. 1, a solar cell 100, according to an exemplary embodiment, is shown. The solar cell 100 includes a substrate 101 with a surface 1012. A back metal contact layer 102, a P-type semiconductor layer 103, a P-N junction layer 104, an N-type semiconductor layer 105, a transparent conductive oxide (TCO) layer 106, and a front metal contact layer 107 are formed on the surface 1012 of the substrate 101 in the order written.

The substrate 101 is flexible and made of stainless steel. The stainless steel can be, but not limited to, Austenitic stainless steel, Ferritic stainless steel, or Martensitic steel. The substrate 101 can be a stainless steel thin foil. A thickness of the substrate 101 is in an approximate range from 10 microns to 100 microns.

The back metal contact layer 102 can be made of silver, copper, molybdenum, aluminum, copper aluminum alloy, silver copper alloy, or copper molybdenum alloy. The back metal contact layer 102 can be formed on the substrate 101 by any of a variety of common techniques including, but not limited to, sputtering.

The P-type semiconductor layer 103 can be made of P-type amorphous silicon (P-a-Si), particularly, P-type amorphous silicon with hydrogen (P-a-Si:H). Also, the P-type semiconductor layer 103 can be made of III-V group compound semiconductors or II-VI group compound semiconductors, particularly above semiconductors doped with aluminum, gallium, or indium, e.g., aluminum gallium nitride (AlGaN), aluminum gallium arsenide (AlGaAs). The P-type semiconductor layer 103 can be formed by plasma enhanced chemical vapor deposition (PECVD).

The P-N junction layer 104 can be made of III-V or I-III-VI group compound semiconductors, e.g., cadmium telluride (CdTe), copper indium diselenide (CulnSe₂, CIS). Also, The P-N junction layer 104 can be made of copper indium gallium diselenide (Culn₁₋ₓGaSe₂, CIGS). The P-N junction layer 104 can be formed on the P-type semiconductor layer using any of a variety of common techniques including, but not limited to, chemical vapor deposition, or sputtering.

The N-type semiconductor layer 105 can be made of N-type amorphous silicon (N-a-Si), particularly, N-type amorphous silicon with hydrogen (N-a-Si:H). Also, the N-type semiconductor layer 105 can be made of III-V group compound semiconductors or II-VI group compound semiconductors, particularly above semiconductors doped with nitrogen, phosphorus, arsenic, e.g., gallium nitride (GaN), indium gallium phosphide (InGaP). The N-type semiconductor layer 105 can be formed by, for example, PECVD.

The TCO layer 106 can be made of indium tin oxide (ITO) or zinc oxide. The TCO layer 106 can be formed by for example, sputtering.

The front metal contact layer 107 can be made of silver, copper, molybdenum, aluminum, copper aluminum alloy, silver copper alloy, or copper molybdenum alloy. The front metal contact layer 107 can be formed on the TCO layer 106 using any of a variety of common techniques including, but not limited to, sputtering. The front metal contact layer 107 has a high electrical conductivity. The front metal contact layer 107 can be formed by, for example, sputtering.

One or more anti-reflective coatings (not shown) can be applied on the front metal contact layer 107 to improve the solar cell's 10 ability of collecting incident light.

In order to improve the waterproofing ability of the solar cell 10, a protective layer (not shown) can be formed on the front metal contact layer 107. The protective layer can be made of resin.

In the present embodiment, the solar cell 10 has a flexible substrate 101 made of stainless steel. Accordingly, the solar cell 10 is flexible, and capable of conforming different shapes of the application. The solar cell 10 can be used in, for example, architecture, and etc. Furthermore, stainless steel is relatively cheap, thus reducing cost of the solar cell 10.

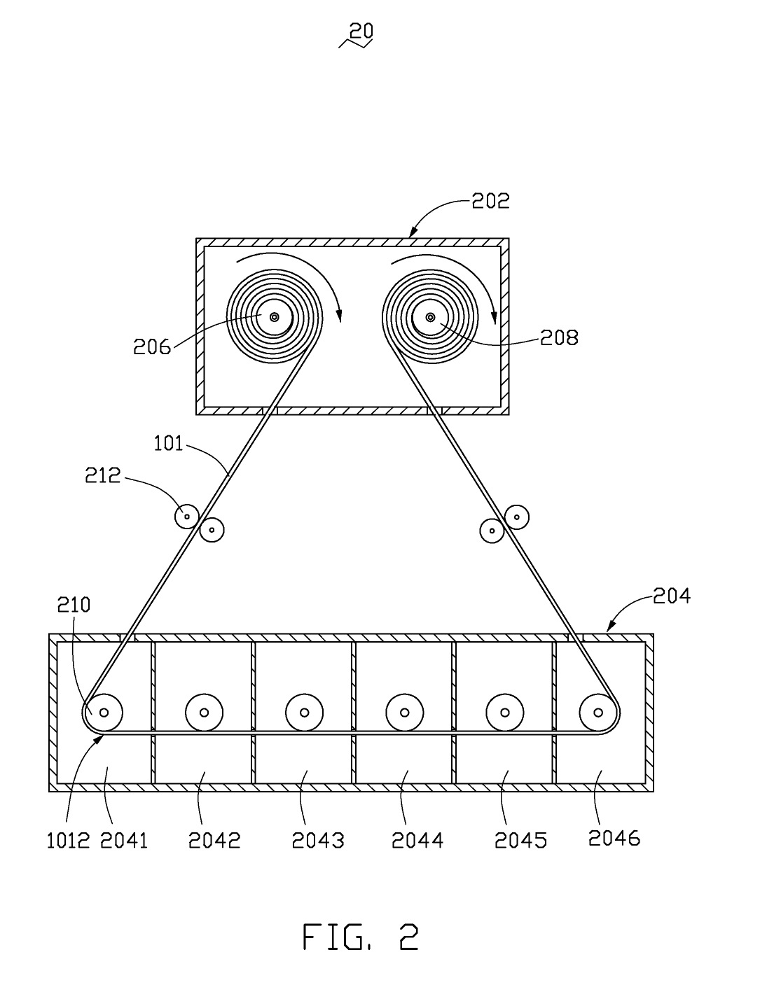

Referring to FIG. 2, a web coating apparatus 20 for making the solar cell 10 of FIG. 1 is shown. The web coating apparatus 20 includes a winding compartment 202 and a deposition compartment 204. The deposition compartment 204 includes a first chamber 2041, a second chamber 2042, a third chamber 2043, a fourth chamber 2044, a fifth chamber 2045, and a sixth chamber 2046, in the order written. The winding compartment 202 has a pay-off roller 206 and a take-up roller 208 disposed therein. The substrate 101 is wound around the pay-offer 206. The pay-off roller 206 is configured for unwinding the substrate 101 therefrom. The take-up roller 208 is configured for driving the substrate 101 to pass through the first chamber 2041 to the sixth chamber 2046 in sequence and then winding the substrate 101 after deposition.

The first chamber 2041 is configured for forming the back metal contact layer 102 by, for example, sputtering. A material of a sputtering target (not shown) depends on a material of the back metal contact layer 102. The material of the sputtering target can be selected from the group consisting of silver, copper, molybdenum, aluminum, copper aluminum alloy, silver copper alloy, or copper molybdenum alloy.

Similarly, the third chamber 2043 is configured for forming the P-N junction layer 102 by, for example, sputtering. The fifth chamber 2045 is configured for forming the TCO layer 106 by, for example, sputtering. The sixth chamber 2046 is configured for forming the front metal contact layer 107 by, for example, sputtering.

The second chamber 2042 is configured for forming the P-type semiconductor layer 103 by, for example, plasma enhanced chemical vapor deposition (PECVD). Likewise, the fourth chamber 2044 is configured for forming the N-type semiconductor layer 105 by, for example, PECVD.

Each chamber has at least one roller 210 disposed therein. The roller 210 is configured for supporting the substrate 101. The roller 210 can be connected with an engine (not shown) such that the roller 210 further drives the substrate 101 to pass through the first chamber 2041 to the sixth chamber 2046 in sequence. The rollers 210 can be filled with a cooling liquid (not shown) configured for heat dissipation of the substrate 101, thus keeping the substrate 101 at a relatively low temperature. Two pairs of guide rollers 212 are positioned between the winding compartment 202 and the deposition compartment 204. The guide rollers 212 are configured for guiding the substrate 101 to move towards the take-up roller 208. The guide rollers 212 can also be connected with an engine (not shown) such that the guide rollers 212 further drives the substrate 101 to advance towards the take-up roller 208.

A method for making the solar cell 10 using the web coating apparatus 20 includes the following steps.

Firstly, the substrate 101 is provided. A first end of the substrate 101 is rolled up in the pay-off roller 206, a second end of the substrate 101 is rolled up in the take-up roller after passing the guide rollers 212 and the rollers 210. The substrate 101 can be, for example, a stainless steel thin foil.

Secondly, the take-up roller 208 is driven to rotate clockwise using, for example, an engine (not shown). Then the substrate 101 is driven by the take-up roller 208 to move towards the take-up roller 208, and then rolled up in the take-up roller 208. The pay-off roller 206 can also be driven to rotate clockwise by an engine (not shown) such that the substrate 101 is further driven to move towards the take-up roller 208. The guide rollers 212 and the rollers 210 can also be driven to rotate counterclockwise using an engine (not shown) such that the substrate 101 is even further driven to advance towards the take-up roller 208.

Thirdly, in the first chamber 2041, the substrate 101 is cooled by the rollers 210. The back metal contact layer 102 is formed on the surface 1012 of the substrate 101 by, for example, sputtering. That is, the substrate 101 has a part with the back metal contact layer 102 formed thereon.

Fourthly, the substrate 101 is driven to move towards the take-up roller 208. When the part of the substrate 101 with the back metal contact layer 102 formed thereon reaches the second chamber 2042, the substrate 101 is again cooled by the rollers 210. Then the P-type semiconductor layer 103 is formed on the back metal contact layer 102 by, for example, PECVD.

Likewise, the substrate 101 is driven to pass through the third chamber 2043, the fourth chamber 2044, the fifth chamber 2045, and the sixth chamber 2046 in the order written. Accordingly, the P-N junction layer 104, the N-type semiconductor layer 105, the TCO layer 106, and the front metal contact layer 107, are formed on the P-type semiconductor layer in the order written. Thus, the solar cell 10 of FIG. 1 is done. The solar cell 10 has a flexible substrate 101 made of stainless steel. Accordingly, the solar cell 10 is flexible, and capable of conforming different shapes of the application.

While certain embodiments have been described and exemplified above, various other embodiments will be apparent to those skilled in the art from the foregoing disclosure. The present invention is not limited to the particular embodiments described and exemplified but is capable of considerable variation and modification without departure from the scope of the appended claims.

What is claimed is:

1. A solar cell comprising:
a flexible substrate, the substrate being comprised of stainless steel;
a back metal contact layer formed on the substrate;
a P-type semiconductor layer formed on the back metal contact layer;
a P-N junction layer formed on the P-type semiconductor layer;
an N-type semiconductor layer formed on the P-N junction layer; and
a front metal contact layer formed on the N-type semiconductor layer.

2. The solar cell as claimed in claim 1, wherein the stainless steel is selected from the group consisting of: Austenitic stainless steel, Ferritic stainless steel, and Martensitic steel.

3. The solar cell as claimed in claim 1, wherein a thickness of the substrate is in an approximate range from 10 microns to 100 microns.

4. The solar cell as claimed in claim 1, wherein the back metal contact layer is comprised of silver, copper, molybdenum, aluminum, copper aluminum alloy, silver copper alloy, or copper molybdenum alloy.

5. The solar cell as claimed in claim 1, wherein the P-type semiconductor layer is comprised of P-type amorphous silicon, aluminum gallium nitride, or aluminum gallium arsenide.

6. The solar cell as claimed in claim 1, wherein the P-N junction layer is comprised of cadmium telluride, copper indium diselenide, or copper indium gallium diselenide.

7. The solar cell as claimed in claim 1, wherein the N-type semiconductor layer is comprised of N-type amorphous silicon, gallium nitride, or indium gallium phosphide.

8. The solar cell as claimed in claim 1, wherein the front metal contact layer is comprised of silver, copper, molybdenum, aluminum, copper aluminum alloy, silver copper alloy, or copper molybdenum alloy.

9. The solar cell as claimed in claim 1, further comprising a transparent conductive oxide layer sandwiched between the N-type semiconductor layer and the front metal contact layer.

10. The solar cell as claimed in claim 9, wherein a material of the transparent conductive oxide layer is selected from the group consisting of indium tin oxide and zinc oxide.
